(19) United States
(12) Patent Application Publication
(10) Pub. No.: US 2004/0094838 A1
(43) Pub. Date: May 20, 2004

(54) Method for forming metal wiring layer of semiconductor device

(76) Inventors: Jung-Hun Seo, Gangneung-City (KR); Gil-Heyun Choi, Yongin-City (KR); Byung-Hee Kim, Seoul (KR); Joo-Young Yun, Seoul (KR); Seong-Geon Park, Yonging-City (KR)

Correspondence Address: HARNESS, DICKEY & PIERCE, P.L.C., P.O. BOX 8910, RESTON, VA, 20195, US

(21) Appl. No.: 10/365,385

(22) Filed: Feb. 13, 2003

(30) Foreign Application Priority Data
Nov. 19, 2002 (KR) 2002-72092

(51) Int. Cl. H01L 23/48; H01L 21/4763; H01L 29/40

(52) U.S. Cl. 257/750; 438/622; 438/642; 438/643

(57) ABSTRACT

A method for forming a metal wiring layer of a semiconductor device, where a first layer having a recess region is formed on a semiconductor substrate. A second layer is formed on inner walls of the recess region and on an upper portion of the first layer. A third layer is formed on the second layer so as to have a smaller third layer thickness on the inner walls of the recess region than on the upper portion of the first layer. A fourth layer is then formed on the-third layer, providing a metal wiring layer with improved step coverage.

### CROSS-REFERENCE TO RELATED CASES

This application claims priority to Korean Patent Application No. 2002-72092, filed Nov. 19, 2002 in the Korean Intellectual Property Office, the contents of which are hereby incorporated by reference herein in its entirety.

### BACKGROUND OF THE INVENTION

1. Field of the Invention

The present invention relates to a method for forming a metal wiring layer of a semiconductor device.

2. Description of the Related Art

As the critical dimensions (CD) of circuits are being reduced, deposition processes for forming a wiring layer using a conventional method (e.g., forming a semiconductor device with an aluminum wiring layer) have developed technical limitations. For example, the conventional method consists of filling a contact hole as a connection portion of a lower conductive layer, and using an upper aluminum wiring layer, or a via hole, as a connection portion of a lower aluminum wiring layer. Since the upper aluminum wiring layer uses a wiring material, it is necessary to electrically connect the lower layer to the upper layer.

A plurality of techniques have been developed to obtain improved electric characteristics when aluminum is used for filling recess regions, such as contact holes or via holes (hereafter referred to as a contact hole) and a trench. In the deposition process for forming a metal wiring layer having a CD less than 0.25 μm (the metal wiring layer being part of a next generation memory device, for example), a physical vapor deposition (PVD) process, such as sputtering, cannot be used alone (e.g., by itself, without other deposition processes). This is due to a large aspect ratio of the contact hole. Accordingly, the aluminum wiring layer is formed instead using a chemical vapor deposition (CVD) process, which has better step coverage than a PVD process.

However, when the aspect ratio of the recess region (contact hole) is increased, the step coverage of the aluminum layer formed by CVD, hereafter a “CVD-Al layer”, depends on the thickness and type of an underlying layer. In general, when forming the CVD-Al layer, the deposition rate of aluminum on the underlying layer increases as the thickness of the underlying layer increases. For example, in a case where a titanium nitride (TiN) layer formed by PVD, which has a bad step coverage, is used as the underlying layer (e.g., wetting layer), the wetting layer is deposited thinly on the inner walls of the recess region, such as the contact hole, while being deposited thickly at the outside of the recess region. If the CVD-Al layer is formed on this wetting layer, a relatively thick aluminum layer is formed at the outside of the recess region, and a relatively thin aluminum layer is formed on the inner walls of the recess region. Thus, the step coverage of the aluminum wiring layer deteriorates.

Accordingly, as the aspect ratio of the contact hole increases, the CD of the contact hole decreases, making it difficult to deposit aluminum on the inner walls of the contact hole, and fill the contact hole with aluminum, adequately on the CVDAl layer, despite the wetting layer being formed by CVD.

### SUMMARY OF THE INVENTION

An exemplary embodiment of the present invention provides a method for forming a metal wiring layer. The metal wiring layer has improved step coverage, so as to improve a metal deposition rate on inner walls of a recess region within a semiconductor device containing the metal wiring layer, as compared to a metal deposition rate at an outside of the recess region, when forming the metal wiring layer to fill the recess region.

Another exemplary embodiment provides a method for forming a metal wiring layer of a semiconductor device to deposit a metal layer on inner walls of a recess region within the semiconductor device that has a large aspect ratio and a small critical dimension (CD), and to fill the recess region with the metal layer without defects, voids or discontinuities.

According to a further exemplary embodiment, the present invention is directed to a method for forming a metal wiring layer of a semiconductor device, where a first layer (insulating layer pattern) having a recess region is formed on a semiconductor substrate. A second layer (barrier metal layer) may be formed on the inner walls of the recess region and on the upper portion of the first layer. A third layer (step coverage control layer) may be formed on the second layer. The third layer may have a thickness on the inner walls that is smaller than a thickness on the upper portion. A fourth layer (aluminum layer) may be formed on the third layer.

The recess region may form a contact hole, which exposes a conductive region of the semiconductor substrate. The recess region may be embodied as a trench, which is formed to a thickness smaller than the thickness of the insulating layer pattern.

The second layer, or barrier metal layer, may comprise titanium nitride (TiN), for example, and the TiN layer may be formed by a chemical vapor deposition (CVD) process or a physical vapor deposition (PVD) process. The barrier metal layer may also be formed of a stack structure of titanium (Ti) layer\TiN layer, with the Ti layer and the TiN layer of the stack structure formed by CVD or PVD.

The third layer, or step coverage control layer on the inner walls of the recess region may be formed to a thickness greater than 0 Å, but less than 20% of the thickness of the step coverage control layer on the upper portion of the first layer (insulating layer pattern).

The step coverage control layer may be a Ti layer or a tantalum (Ta) layer formed by PVD, or a Ti layer or Ta layer formed by a plasma CVD process, for example. In order to control the thickness of the step coverage control layer, a microwave power, and flow rate of a source gas supplied in the plasma CVD process may be controlled. The step coverage control layer may also be a TiN layer or a tantalum nitride (TaN) layer formed by the plasma CVD process. To control thickness, the microwave power applied and the flow rates of the source gases supplied in the plasma CVD process may also be controlled.

The fourth layer, which may be an aluminum layer or aluminum alloy layer, may be formed by a metal organic CVD (MOCVD) process using any of a methylpyrrolidine alane (MPA), dimethylethylamine alane (DMEAA), dimethylaluminium hydride (DMAH), and/or trimethylamine alane (TMAA) precursor, for example.

In another exemplary embodiment, the aluminum layer may be planarized. A chemical mechanical polishing (CMP) method or an etchback method may be used to planarize the aluminum layer. In another exemplary embodiment, a metal layer may be formed on the aluminum layer, and thermal processing may be performed on a resultant structure having the metal layer. The metal layer may be formed of aluminum or an aluminum alloy. The thermal processing may be performed at a temperature of about 350 to 500° C., for example.

According to another exemplary embodiment, the present invention is directed to a method for forming a metal wiring layer of a semiconductor device. An insulating layer pattern that includes a recess region may be formed on a semiconductor substrate, and a first liner that includes a TiN layer, which may be formed by CVD for example, may be formed on the inner walls of the recess region and the upper portion of the insulating layer pattern. A second liner formed of a Ti layer, formed by PVD for example, may be formed on the first liner. A metal wiring layer may be formed in the recess region and on the upper portion of the insulating layer pattern.

The thickness of the second liner may be smaller on the inner walls of the recess region than on the upper portion of the insulating layer pattern. The first liner may be a barrier metal layer formed of a TiN layer, or a stack structure of titanium (Ti) and titanium nitride (TiN) layers. The metal wiring layer may be formed of aluminum or an aluminum alloy. In order to form the metal wiring layer, a first metal layer of aluminum or aluminum alloy may be formed on the second liner by CVD.

In yet a further exemplary embodiment, the method may comprise forming a first metal layer of aluminum or an aluminum alloy on the second liner using CVD, forming a second metal layer of aluminum or an aluminum alloy on the first metal layer using PVD, and thermal processing a resultant structure including the second metal layer to reflow the first metal layer and the second metal layer, so as to form the metal wiring layer.

In another exemplary embodiment, the present invention is directed to a method of forming a metal wiring layer for a semiconductor device. An insulating layer may be formed on a substrate. The insulating layer has an upper portion and a recessed formed therein, the recess having sidewalls. A barrier metal layer may be formed over the upper portion and recess of the insulating layer, and a step coverage control layer of variable thickness may be formed over the barrier metal layer. A metal wiring layer is formed over the step coverage control layer. A thickness of the step coverage control layer may be thinner near or within the recess than near or on top of the upper portion of the insulating layer.

In another exemplary embodiment, the present invention is directed to a method of forming a metal wiring layer for a semiconductor device where an insulating layer is formed on a substrate. The insulating layer includes an upper portion and a recess formed therein, the recess having sidewalls. A first liner may be formed over the upper portion and recess of the insulating layer, and a second liner of variable thickness may be formed over the first liner. A metal wiring layer may be formed over the second liner within the recess and over the upper portion of the insulating layer. The thickness of the second liner may be thinner near or within the recess than a thickness of the second liner near or on top of the upper portion.

According to various exemplary embodiments of the present invention, a deposition rate of the metal layer on the inner walls of the recess region may be increased, as compared to a deposition rate at the outside of the recess region, when forming the metal wiring layer. The resulting metal wiring layer may thus have improved step coverage. In addition, a deposition state and filling state of the metal layer in the recess region may be improved, even when the recess region has a large aspect ratio and a small critical dimension (CD).

### BRIEF DESCRIPTION OF THE DRAWINGS

The present invention will become more apparent by describing in detail exemplary embodiments thereof with reference to the attached drawings, in which:

FIGS. 1 through 5 are sectional views illustrating a method for forming a metal wiring layer of a semiconductor device according to an exemplary embodiment of the present invention;

FIG. 6 is a graph illustrating the growth rates of aluminum layers formed by chemical vapor deposition (CVD) according to an exemplary embodiment of the present invention;

FIG. 7 illustrates surface morphology photographs of CVD-Al layers according to an exemplary embodiment of the present invention, and a CVD-Al layer according to a conventional method;

FIG. 8 illustrates photographs showing deposition characteristics of a CVD-Al layer according to the conventional method; and

FIG. 9 illustrates photographs showing deposition characteristics of a CVD-Al layer according to an exemplary embodiment of the present invention.

### DETAILED DESCRIPTION

The present invention and exemplary embodiments thereof are described more fully with reference to the accompanying drawings. This invention may, however, be embodied in many different forms and should not be construed as being limited to the exemplary embodiments set forth herein; rather, these exemplary embodiments are provided so that this disclosure is thorough and complete, and conveys the concept of the invention to those skilled in the art. In the drawings, the thickness of layers and regions are exaggerated for clarity. When a layer is referred to as being “on” another layer or substrate, the layer may be directly on the other layer or substrate, or intervening layers may also be present.

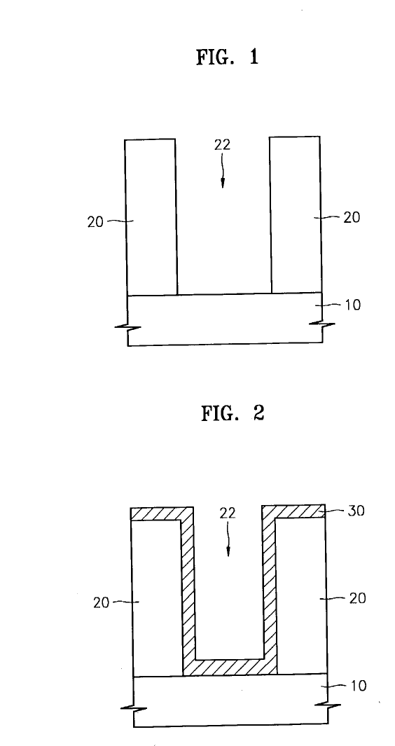

FIGS. 1 through 5 are sectional views illustrating a method for forming a metal wiring layer of a semiconductor device according to an exemplary embodiment of the present invention.

Referring to FIG. 1, an insulating layer pattern 20 having a recess region 22 is formed on a semiconductor substrate 10. The insulating layer pattern 20 may form an inter-level insulating layer for separate unit devices, or separate layers in a multi-layer structure. The recess region 22 may form a contact hole for exposing a conductive region (not shown) of the semiconductor substrate 10, as shown in FIG. 1. In another aspect, the recess region 22 may form a trench, which has a thickness less than the thickness of the insulating layer pattern 20.

Referring to FIG. 2, a barrier metal layer 30 may be formed on the inner walls of the recess region 22 and on the upper portion of the insulating layer pattern 20. The barrier metal layer 30 can be formed of titanium nitride (TiN), or a stack structure of titanium (Ti) layer\TiN layers, for example. The TiN layer of the barrier metal layer 30 forms a first liner, which may act as a wetting layer in a subsequent metal wiring layer forming process. The Ti layer may be formed by a chemical vapor deposition (CVD) process or a physical vapor deposition (PVD) process. The TiN layer may also be formed by CVD or PVD; however, in this exemplary embodiment the TiN layer is formed by CVD.

Referring to FIG. 3, a step coverage control layer 40, configured as a second liner, may be formed on the barrier metal layer 30. The step coverage control layer 40 on the inner walls of recess region 22 is thinner than the step coverage control layer 40 on the upper portion of the insulating layer pattern 20. In other words, the thickness t₂ of the step coverage control layer 40 on the inner walls of the recess region 22, particularly on the bottom of the recess region 22, is smaller than the thickness t₁ of the step coverage control layer 40 on the upper portion of the insulating layer pattern 20 (t₁>t₂), as shown in FIG. 3. The thickness t₂ of the step coverage control layer 40 on the inner walls of the recess region 22 may be larger than 0 Å and smaller than 20% of the thickness t₁ of the step coverage control layer 40 on the upper portion of the insulating layer pattern 20 (0 Å<t₂<0.2t₁). When the aspect ratio of the recess region 22 is larger than 10, the thickness t₂ of the step coverage control layer 40 on the inner walls of the recess region 22 may be larger than 0 Å, but smaller than 10% of the thickness t₁ of the step coverage control layer 40 on the upper portion of the insulating layer pattern 20 (0Å<t₂<0.1t₁). The step coverage control layer 40, having different thicknesses based on its location (e.g., within recess 22 or an upper portion of insulating layer pattern 20, etc.) can be formed as any one of a Ti layer, TiN layer, tantalum (Ta) layer, or tantalum nitride (TaN) layer, for example. However, layers of other component metals could also be used, as would be apparent to one of ordinary skill in the art.

When the step coverage control layer 40 is formed of Ti or Ta, the Ti layer or the Ta layer may be formed by PVD, in order to obtain desired step coverage characteristics. Alternatively, the step coverage control layer 40 comprising Ti or Ta may be formed by a plasma CVD process. In this case, power (e.g., microwave power) and flow rate of a Ti source gas or a Ta source gas, supplied in the plasma CVD process, are controlled to control the thickness of the step coverage control layer 40. In other words, an increased microwave power and a reduced flow rate of the source gas are supplied, as compared to the conventional plasma CVD process of forming the Ti or Ta layer.

For example, in the conventional plasma CVD process, a microwave power of about 300 W and a flow rate (of titanium chloride (TiCl₄) as the source gas) of about 5 sccm are supplied. In the CVD process according to an exemplary embodiment of the present invention, a microwave power of more than about 700 W is applied, and a flow rate of TiCl₄ is supplied at less than about 2 sccm. Where the underlying (e.g., wetting) layer for an aluminum layer is formed using Ti, a grooving phenomenon, which typically may occur after etching of a metal layer, is less likely to occur, unlike a case where the underlying layer is formed using TiN. Accordingly, when Ti is used for forming the step coverage control layer 40, the likelihood of defects due to the grooving phenomenon, which may occur after the etching process of the metal layer of aluminum or an aluminum alloy on the Ti layer, may be reduced.

A plasma CVD process may be used when forming the step coverage control layer 40 of TiN or TaN. Similar to the previous discussion of forming the step coverage control layer 40 of Ti, the microwave power and flow rates of the source gases supplied in the plasma CVD process are controlled in order to control the thickness of the step coverage control layer 40. In the conventional CVD process for forming the TiN layer, a microwave power of about 300 W is applied, and the flow rates of TiCl₄ and nitrogen hydride (NH₂) as the source gases are supplied at about 30 sccm and 100 sccm, respectively. According to an exemplary embodiment of the present invention, a microwave power of more than about 700 W is applied, and the flow rates of TiCl₄ and NH₂ as the source gases are supplied at less than about 1 sccm and 10 sccm, respectively.

As describe above, the step coverage control layer 40, which has a thickness t₂ on the bottom of the recess region 22 thinner than the thickness t₁ on the upper portion of the insulating layer pattern 20, is formed on the barrier metal layer 30. Thus, the deposition rate of the metal wiring layer may be faster near or in the recess region 22 than that of the metal wiring layer at the outside of the recess region 22 (e.g., nearer upper portion of insulating layer pattern 20) when depositing the metal wiring layer thereon using CVD techniques. Accordingly, the step coverage of the metal wiring layer is increased, and the deposition state and filling state of the metal wiring layer within recess region 22 are improved. The process of using the step coverage control layer 40 may be referred to as a selective wetting process-Al (SWP-Al) process, which will be described in further detail below.

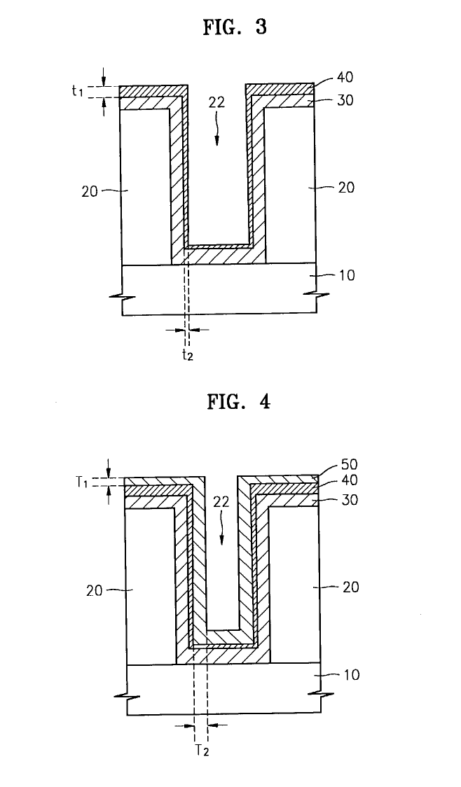

Referring to FIG. 4, a first metal layer 50 is formed on the step coverage control layer 40 by CVD. Here, the first metal layer 50 may be formed of Al or an Al alloy. In order to form the first metal layer 50, a metal organic CVD (MOCVD) process using methylpyrrolidine alane (MPA), dimethylethylamine alane (DMEAA), dimethylaluminum hydride (DMAH), or trimethylamine alane (TMAA) precursor can be used.

As described above, the first metal layer 50 may be formed on the step coverage control layer 40, which has a thickness (t₂) on the bottom of the recess region 22 that is thinner than that on the upper portion (t₁) of the insulating layer pattern 20. Thus, the deposition rate of the first metal layer 50 is faster in the recess region 22 than the deposition rate at the outside of the recess region 22. As a result, the thickness of the first metal layer 50 on the inner walls of the recess region 22 is larger than the thickness of the first metal layer 50 on the upper portion of the insulating layer pattern 20. In other words, a thickness T₂ of the first metal layer 50 on the inner walls of the recess region 22, particularly near or on the bottom of the recess region 22, is larger than a thickness T₁ of the first metal layer 40 on or near the upper portion of the insulating layer pattern 20 (e.g., T₁<T₂), as shown in FIG. 4. Since the deposition rate of the metal layer increases in the recess region 22, a deposition characteristic and a filling characteristic of the first metal layer 50 in the recess region 22 are each increased. Further, in order to form a metal plug of the first metal layer 50 within recess region 22, the first metal layer 50 may be planarized by a chemical mechanical polishing (CMP) process or an etchback process, as is known.

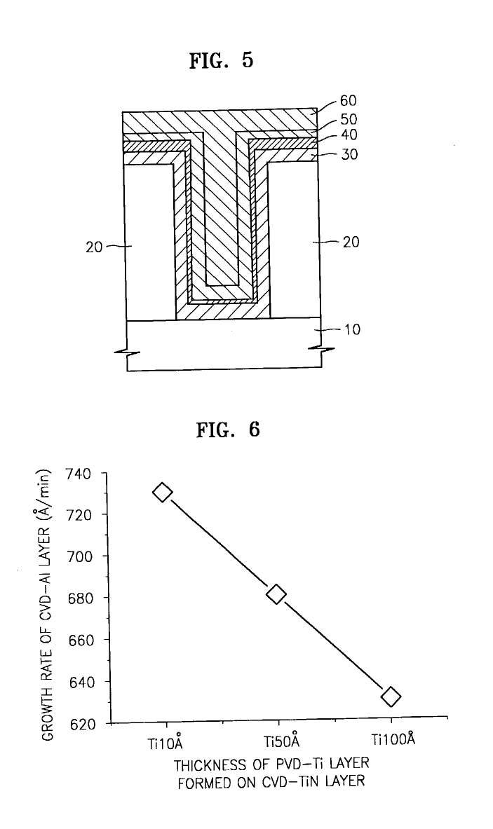

Referring now to FIG. 5, a second metal layer 60 may be formed on the first metal layer 50 by PVD, for example. The second metal layer 60 may comprise aluminum or an aluminum alloy. The second metal layer 60 is formed only on the first metal layer 50 in FIG. 5; however, the second metal layer 60 may be formed directly on the step coverage control layer 40 at the outside of the recess region 22. The second metal layer may be formed directly on step coverage control layer 40 after the first metal layer 50 is planarized.

In order to reflow the first metal layer 50 and the second metal layer 60, the resultant structure (including the second metal layer 60) is thermally processed. The thermal process may be performed at a temperature of about 350 to 500° C., for example. As a result, a metal wiring layer is formed, with the first metal layer 50 and the second metal layer 60 having been mixed, while the metal wiring layer has a planarized upper surface.

The deposition rate of the aluminum layer formed by CVD largely depends on the characteristics of the underlying layer, such as the kind or type of layer, the deposition process used, and the thickness of the underlying layer. Accordingly, in another exemplary embodiment, a method of improving the step coverage of the CVD-Al layer in the recess region, such as a contact hole or trench, has been developed by using the characteristics of the CVD-Al layer. The CVD-Al layer's deposition rate largely depends on the characteristics of the underlying layer.

FIG. 6 is a graph illustrating the growth rates of CVD-Al layers formed on PVD-Ti layers, which are formed on the CVD-TIN layer, having different thicknesses, according to an exemplary embodiment of the present invention. In order to attain the results shown in FIG. 6, oxide layers were formed on wafers to a thickness of 1,000 Å, and the CVD-TiN layers (analogous to barrier metal layer 30) were formed, thereon to a thickness of 50 Å. The PVD-Ti layers (analogous to step coverage control layer 40) were formed on the CVD-TiN layers to thicknesses of 10 Å, 50 Å, and 100 Å, respectively, and a deposition process of the CVD-Al layers (analogous to first and second metal layers 50, 60) was performed on the CVD-TiN layers for 60 seconds. Referring to FIG. 6, when the PVD-Ti layer was deposited to create a thickness of 10 Å on the CVD-TiN layer (the CVA-TiN layer has a thickness of 50 Å), the deposition rate of the CVD-Al layer was increased by about 25%, as compared to the case where the PVD-Ti layer was deposited at a thickness of 100 Å.

If the above processes are applied to the process of forming the contact hole or trench, when the step coverage of the CVD-TiN layer on the inner walls of the contact hole is 100%, and the step coverage of the PVD-Ti layer on the inner walls of the contact hole is about 10%, the CVD-TiN layer and the PVD-Ti layer are sequentially deposited to thicknesses of 50 Å and 100 Å, respectively, at the outside of the contact hole. Also, the CVD-TiN layer and the PVD-Ti layer are deposited to thicknesses of 50 Å and 10 Å, respectively, on the inner walls of the contact hole. Thus, the deposition rate of the CVD-Al layer on the inner walls of the contact hole increases by about 25%, as compared to the deposition rate at the outside of the contact hole. Therefore, a CVD-TiN layer having formed excellent step coverage, and a PVD-Ti layer having poor step coverage, are sequentially formed (e.g., one layer after the other layer). The deposition characteristics of the CVD-Al layer, which depends on step coverages of the underlying layers (e.g., PVD-Ti and CVD-TiN layers), are thus used to improve the step coverage of the CVD-Al layer.

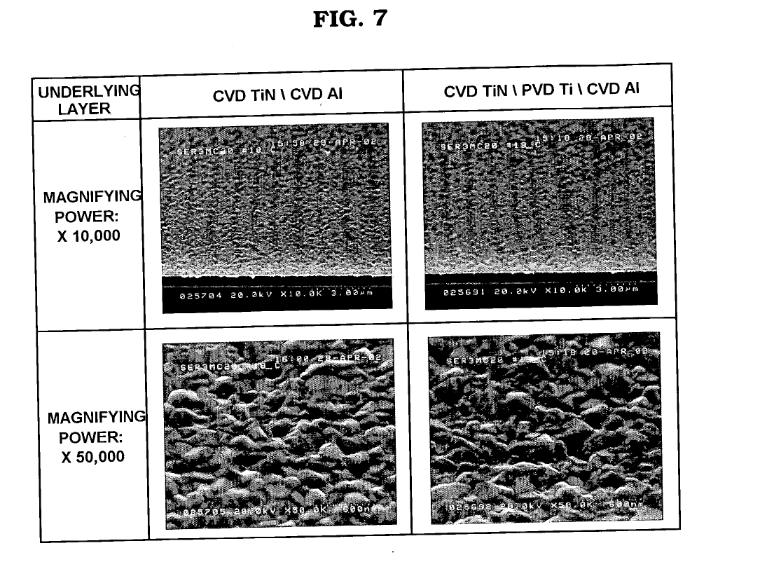

FIG. 7 illustrates surface morphology photographs of CVD-Al layers of a CVD-TiN layer\PVD-Ti layer\CVD-Al layer combination according to an exemplary embodiment of the present invention, and a CVD-TiN layer\CVD-Al layer combination according to the conventional method.

In FIG. 7, when the CVD-Al layers were formed to a thickness of 600 Å on the underlying layer of the CVD-TIN layer (having a thickness of 50 Å) and on the underlying layer of the CVD-TIN layer\PVD-Ti layer (having thicknesses of 50 Å and 100 Å, respectively), the surfaces of the CVD-Al layers were smooth, while maintaining reflective index values of over 210. Accordingly, a method for forming the metal wiring layer according to an exemplary embodiment of the present invention does not deteriorate a subsequent photolithograph process used for forming a semiconductor device. In the case where the underlying layer (the CVD-TiN layer\PVD-Ti layer) is formed, if the PVD-Al layer is formed on the CVD-Al layer, the PVD-Al layer is subjected to a reflow process, and the aluminum wiring layer is formed by etching the PVD-Al layer. The aluminum wiring layer was observed using a scanning electron microscope (SEM) scanning in a in-line manner. As shown in FIG. 7, the aluminum wiring layer did not exhibit the aforementioned grooving phenomenon, which causes defects in the layer due to the etching process.

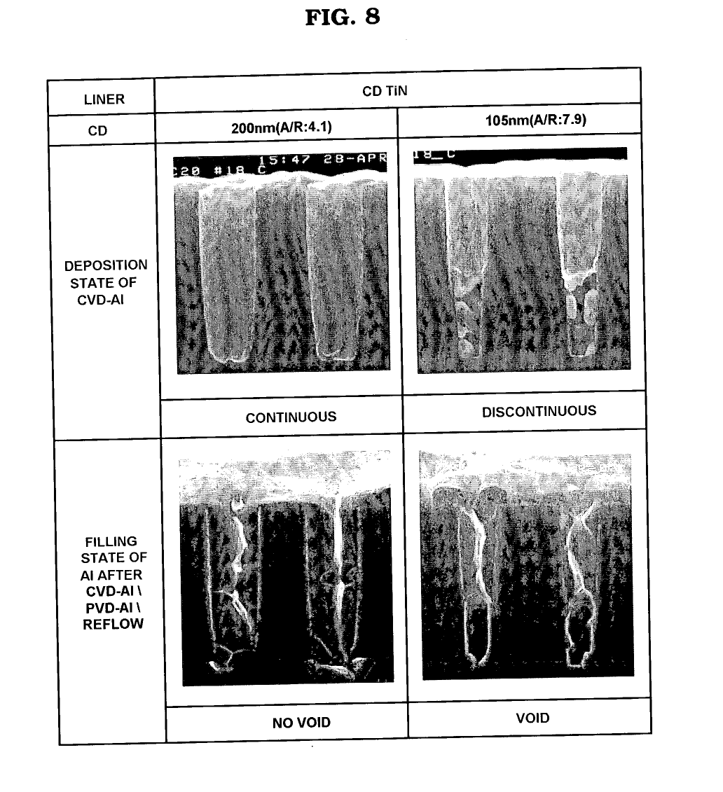

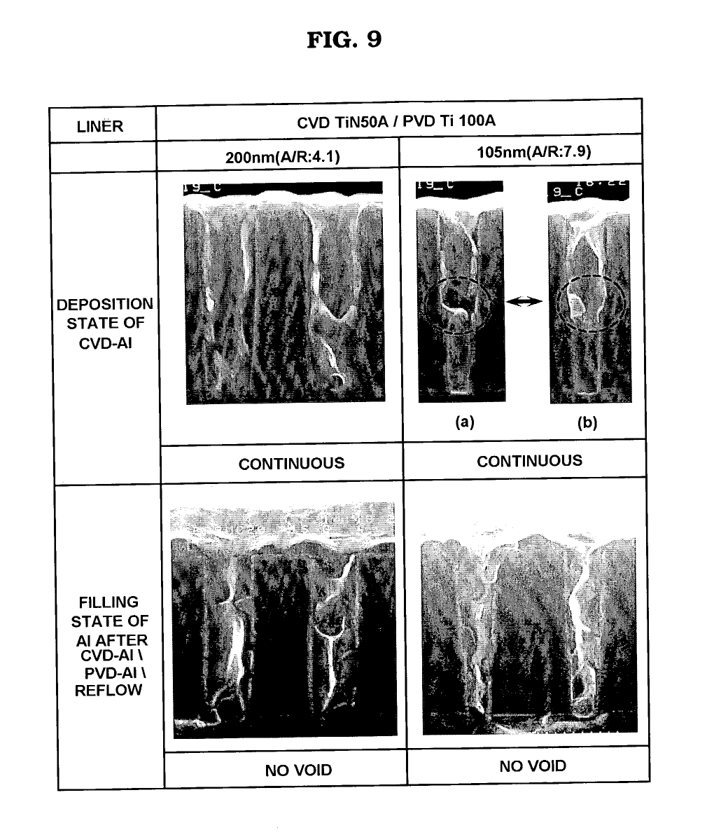

FIGS. 8 and 9 illustrate photographs showing the deposition characteristics of CVD-Al layers of a CVD-TiN layer\CVD-Al layer combination according to the conventional method, and of a CVD-TiN layer\PVD-Ti layer\CVD-Al layer combination according to an exemplary embodiment of the present invention.

In order to attain the results shown in FIGS. 8 and 9, a CVD-TiN layer having the thickness of 50 Å was used, alone, as a wetting layer liner. A CVD-TiN layer\PVD-Ti layer combination having thicknesses of 50 Å and 100 Å, respectively, was used as the wetting layer liner, for the cases where the CDs of the contact hole were 200 nm and 105 nm, while maintaining a contact hole step difference of 8,300 Å. Thereafter, aluminum wiring layers were formed on the wetting layer liners to observe the deposition states and the filling states of the aluminum wiring layers. The aluminum wiring layers were formed by depositing the CVD-Al layer for 50 seconds, forming the PVD-Al layer to the thickness of 7,400 Å, and performing a reflow at a temperature of 585° C. for three (3) minutes.

As shown in FIGS. 8 and 9, when the step difference is 8,300 Å and the bottom CD is 200 nm, (i.e., this indicates an aspect ratio of 4.1), continuous CVD-Al layers were formed in the contact holes and the CVD-Al layers completely filled the contact holes without a void after reflow (see left-hand side pictures in FIGS. 8, 9). This was true where the liner was a CVD-TiN layer (FIG. 8) and where the liner was formed of a CVD-TiN layer\PVD-Ti layer combination (FIG. 9).

However, when the bottom CD is 105 nm, (i.e., indicating an aspect ratio of 7.9, see right-hand side pictures in FIGS. 8 and 9), and the liner comprises a CVD-TiN layer, the continuous CVD-Al layer was not formed in the lower portion of the contact hole. Instead, a discontinuous, island-shaped layer was formed. Accordingly, since the CVD-Al layer was broken in the lower portion of the contact hole, a void was formed in the contact hole after the CVD-Al layer\PVD-Al layer\reflow process (lower right picture in FIGS. 8 and 9). The void was formed in the contact hole because the CVD-Al layer blocked the inlet of the contact hole as the CD decreased, so that the depression of the CVD-Al source toward the bottom of the contact hole was reduced.

Further where the CD was 105 nm, (aspect ratio of 7.9), but the liner used was the CVD-TiN layer\PVD-Ti layer according to an exemplary embodiment, the CVD-Al source easily entered into the contact hole. This was due to the deposition rate of aluminum being faster on the inner walls of the contact hole than at the outside of the contact hole. As a result, a continuous CVD-Al layer was formed to the bottom of the contact hole. In FIG. 9, and with the CVD-TiN/PVD-Ti layer, the aluminum layer is broken at the middle of the contact hole in photograph (a). However, the broken portion is formed because the portion of the aluminum layer which fills the contact hole is attached to the opposite portion, as shown in photograph (b), for example, when the contact is cut to evaluate the deposition state of the aluminum layer. Thus, the CVD-Al layer, which is continuously formed in the contact hole and acts as a seed layer, is reflowed to the bottom of the contact hole to obtain a complete filling state without a void after the CVD-Al layer\PVD-Al layer\reflow process.

As a result, even if the aspect ratio of the contact hole is increased by more than 92% (from 4.1 to 7.9), a continuous CVD-Al layer may be formed in the contact hole by using the double liner structure of the CVD-TiN layer\PVD-Ti layer, instead of a single CVD-TiN layer having a step coverage of 100%. As described above, if the CVD-TiN layer is used alone, the deposition rate of the CVD-Al layer is the same on the inner walls of the contact hole and at the outside of the contact hole. However, when the CVD-TiN layer\PVD-Ti layer is formed, the PVD-Ti layer is formed on the inner walls of the contact hole to a thinner (smaller) thickness than at the outside of the contact hole, so that the deposition rate of the CVD-Al layer is increased on the inner walls of the contact hole, as compared to the deposition rate of the CVD-Al layer at the outside of the contact hole. Thus, if a CVD-TiN layer (having excellent step coverage) and a PVD-Ti layer (having poor step coverage) are sequentially formed, to be used as a wetting layer liner for forming the CVD-Al layer, the step coverage of the CVD-Al layer may be significantly increased, without deteriorating the morphology of the surface of the CVD-Al layer, and while increasing the filling margin of the contact hole.

In an exemplary embodiment for forming the metal wiring layer of the semiconductor device, the step coverage control layer is thinner in the vicinity of or on the inner walls of the recess region, than in the vicinity of or on the upper portion of the insulating layer pattern, and is formed on the barrier metal layer. The aluminum layer is formed on the step coverage control layer (e.g., by CVD) when forming the metal wiring layer for filling the recess region, such as the contact hole, in the insulating layer pattern. In other words, the double liner structure of the barrier metal layer, such as the CVD-TiN layer with excellent step coverage, and the step coverage control layer, such as the PVD-Ti layer with poor step coverage, is formed prior to forming the CVD-Al layer, in an effort to improve the step coverage of the CVD-Al layer.

Therefore, the deposition rate of the metal layer on the inner walls of the recess region may be increased, as compared to the deposition rate at the outside of the recess region, when forming the metal wiring layer and filling the recess region. In addition, the deposition state and filling state of the metal layer in the recess region may be improved, even when the recess region has a large aspect ratio and a small CD.

In various exemplary embodiments, layers have been formed by various deposition processes, including CVD, PVD, plasma CVD, MOCVD, etc., it being understood that these deposition process, unless otherwise discussed above, may be interchangeable. In the alternative, deposition processes such as low pressure chemical vapor deposition (LPCVD) and atomic layer deposition (ALD) could be substituted, where applicable, for one of more of the aforementioned processes described in the various exemplary embodiments.

While the present invention has been particularly shown and described with reference to exemplary embodiments thereof, it will be understood by those skilled in the art that various changes in form and detail may be made therein without departing from the spirit and scope of the invention as defined by the appended claims.

What is claimed is:

1. A method for forming a metal wiring layer of a semiconductor device, comprising:
forming a first layer having an upper portion and a recess region on a semiconductor substrate, the recess region having inner walls;
forming a second layer on the inner walls of the recess region and on the upper portion;
forming a third layer on the second layer, the third layer having a thickness on the inner walls of the recess region that is smaller than a thickness of the third layer on the upper portion; and
forming a fourth layer on the third layer.

2. The method of claim 1, wherein the recess region is a contact hole that exposes a conductive region of the semiconductor substrate.

3. The method of claim 1, wherein the recess region is a trench having a thickness that is smaller than a thickness of the first layer.

4. The method of claim 1, wherein the second layer is a barrier metal layer that is formed of titanium nitride (TiN).

5. The method of claim 4, wherein the TiN layer is formed by at least one of a chemical vapor deposition (CVD) process and a physical vapor deposition (PVD) process.

6. The method of claim 1, wherein the second metal layer is a barrier metal layer formed of a stack structure of titanium (Ti) and titanium nitride layers, (Ti layer/TiN layer).

7. The method of claim 6, wherein the Ti layer is formed by at least one of a chemical vapor deposition (CVD) process and a physical vapor deposition (PVD) process.

8. The method of claim 6, wherein the TiN layer is formed by at least one of a chemical vapor deposition (CVD) process or physical vapor deposition (PVD) process.

9. The method of claim 1, wherein the third layer is a step coverage control layer that, on the inner walls of the recess region, is formed to a thickness greater than 0 Å but less than 20% of the thickness of the step coverage control layer on the upper portion of the first layer.

10. The method of claim 1, wherein the third layer is a step coverage control layer composed of at least one of titanium (Ti) and tantalum (Ta) that is formed by a physical deposition (PVD) process.

11. The method of claim 1, wherein the third layer is a step coverage control layer composed of at least one of titanium (Ti) and tantalum (Ta) that is formed by a plasma chemical vapor deposition (CVD) process.

12. The method of claim 11, further comprising controlling a microwave power applied, and a flow rate of a source gas supplied, in the plasma CVD process in order to control thickness of the step coverage control layer.

13. The method of claim 1, wherein the third layer is a step coverage control layer composed of at least one of titanium nitride (TiN) and tantalum nitride (TaN) that is formed by a plasma chemical vapor deposition (CVD) process.

14. The method of claim 13, further comprising controlling a microwave power applied, and a flow rate of a source gas supplied, in the plasma CVD process in order to control thickness of the step coverage control layer.

15. The method of claim 1, wherein the fourth layer is an aluminum layer. formed by a metal organic CVD (MOCVD) process using at least one of a methylpyrrolidine alane (MPA), dimethylethylamine alane (DMEAA), dimethylaluminium hydride (DMAH), and trimethylamine alane (TMAA) precursor.

16. The method of claim 1, further comprising planarizing the fourth layer.

17. The method of claim 16, wherein the fourth layer is an aluminum layer that is planarized by at least one of a chemical mechanical polishing (CMP) method and an etchback process.

18. The method of claim 1, further comprising forming a metal layer on the fourth layer.

19. The method of claim 18, wherein the metal layer is formed by a physical vapor deposition (PVD) process.

20. The method of claim 18, wherein the metal layer includes at least one of aluminum and an aluminum alloy.

21. The method of claim 18, further comprising thermal processing a resultant structure with the metal layer.

22. The method of claim 21, wherein the thermal processing is performed at a temperature of about 350 to 500° C.

23. A method for forming a metal wiring layer of a semiconductor device, comprising:
forming an insulating layer having a recess region and an upper portion on a semiconductor substrate;
forming a first liner that includes a TiN layer on inner walls of the recess region and an the upper portion of the insulating layer;
forming a second liner that includes a Ti layer on the first liner; and
forming a metal wiring layer in the recess region and on the upper portion of the insulating layer.

24. The method of claim 23, wherein the thickness of the second liner is smaller in the vicinity of the inner walls of the recess region than in the vicinity of the upper portion of the insulating layer.

25. The method of claim 24, wherein the second liner on the inner walls of the recess region is formed to a thickness greater than 0 Å but less than 20% of the thickness of the second liner on the upper portion of the insulating layer.

26. The method of claim 23, wherein the first liner is a barrier metal layer comprising at least one of a TiN layer and a stack structure of titanium (Ti) and titanium nitride (TiN) layers.

27. The method of claim 26, wherein the Ti layer is formed by at least one of a chemical vapor deposition (CVD) process and a physical vapor deposition (PVD) process.

28. The method of claim 23, wherein the metal wiring layer includes at least one of aluminum and an aluminum alloy.

29. The method of claim 23, wherein the forming of the metal wiring layer includes forming a first metal layer on the second liner by a chemical vapor deposition (CVD) process.

30. The method of claim 29, wherein the first metal layer is at least one of an aluminum and aluminum alloy layer formed by a metal organic CVD (MOCVD) processing using at least one of a methylpyrrolidine alane (MPA), dimethylethylamine alane (DMEAA), dimethylaluminium hydride (DMAH), and trimethylamine alane (TMAA) precursor.

31. The method of claim 23, wherein the forming of the metal wiring layer includes:
forming a first metal layer of aluminum or an aluminum alloy on the second liner by a chemical vapor deposition (CVD) process;
forming a second metal layer of aluminum or an aluminum alloy on the first metal layer by a physical vapor deposition (PVD) process; and
thermal processing a resultant structure including the second metal layer in order to reflow the first metal layer and the second metal layer.

32. The method of claim 31, wherein the thermal processing is performed at a temperature of about 350 to 500° C.

33. The method of claim 31, further comprising planarizing the first metal layer prior to forming the second metal layer.

34. The method of claim 33, wherein the planarizing is performed by at least one of a chemical mechanical polishing (CMP) process and an etchback process.

35. The method of claim 1, wherein the first layer is an insulating layer pattern.

36. The method of claim 1, wherein the fourth layer is an aluminum layer formed by a chemical vapor deposition (CVD) process.

37. The method of claim 23, wherein
forming said first liner includes forming the first liner using a chemical vapor deposition (CVD) process; and
said forming a second liner includes forming the second liner using a physical vapor deposition (PVD) process.

38. A method of forming a metal wiring layer for a semiconductor device having an insulating layer formed on a substrate, the insulating layer having an upper portion and a recess with side walls, comprising:
forming a barrier metal layer on the upper portion and the recess of the insulating layer,
forming a step coverage control layer of variable thickness on the barrier metal layer; and
forming a metal wiring layer on the step coverage control layer.

39. The method of claim 38, wherein a thickness of the step coverage control layer is thinner near or within the recess than near or on top of the upper portion of the insulating layer.

40. A method of forming a metal wiring layer for a semiconductor device having an insulating layer formed on a substrate, the insulating layer having an upper portion and a recess with sidewalls, comprising:
forming a first liner on the upper portion and the recess of the insulating layer;
forming a second liner of variable thickness on the first liner; and
forming a metal wiring layer in the recess and on the upper portion of the insulating layer.

41. The method of claim 40, wherein a thickness of the second liner is thinner near or within the recess than near or on top of the upper portion.
